(19) United States
(12) Patent Application Publication
(10) Pub. No.: US 2012/0097432 A1
(43) Pub. Date: Apr. 26, 2012

(54) ELECTRODE ARRAY

(75) Inventors: Jen-Shiun Huang, Hsinchu City (TW); Chi-Ming Wu, Tainan City (TW); Heng-Hao Chang, Taipei City (TW)

(73) Assignee: E INK HOLDINGS INC., Hsinchu (TW)

(21) Appl. No.: 13/105,228

(22) Filed: May 11, 2011

(30) Foreign Application Priority Data
Oct. 21, 2010 (TW) 099135985

(51) Int. Cl. H05K 1/03; H05K 3/00; H05K 1/00

(52) U.S. Cl. 174/254; 174/250; 174/255; 29/829

(57) ABSTRACT

An electrode array is provided. The electrode array includes a substrate; and a plurality of electrodes, each of which has a first part with a first width and a second part with a second width different from the first width, wherein the plurality of electrodes are configured in compensation with each other on the substrate.

### FIELD OF THE INVENTION

The present invention relates to an electrode array, in particular to an electrode array including multiple electrodes with variable width or length.

### BACKGROUND OF THE INVENTION

Usually between the display and the external circuit, there is at least one bonding pad used as an interface electrode disposed within the interface region. By electrically linking the bonding pad of the display and that of the external circuit, the display and the external circuit are electrically connected together.

However, with prosperous developments of the electronic technology, the resolution and the responding speed of various displays are continuously enhanced and therefore the signals demanded to be transmitted and received are accordingly increased. But the size for entire the display is unpopular to be increased because of consumers' preferences and fashions; on the contrary, the display are manufactured as slimmer and thinner as possible, due to the miniaturization tendency for the electronic device over the consuming market.

Thus, in order to transmit and receive massive signals within the finite space available on such miniaturized electronic device, for example: a palm display, the amounts of the bonding pads used as transmitting and receiving signals disposed within the respective interface regions on the flexible printing circuit (FPC) board of the display and the external circuit must be increased and the distance between neighboring bonding pads, a.k.a. the pitch, also become smaller correspondingly, in order to allow more and more bonding pads to be arranged and disposed within the finite space available for processing much massive signals. However, such development and implementation will cause the effective electrically bonding area between the bonded bonding pads respectively disposed on different electronic device is reduced thereby.

Please refer to FIG. 1(A), which is a diagram illustrating bonding pads utilized in a conventional display. The display 200 in FIG. 1(A) includes a periphery area 201 and a display area 202. There are multiple bonding pads 203 disposed in the interface region 204 in the periphery area 201. The bonding pads 203 are fabricated on a thin film transistor (TFT) glass substrate 205. These conventional bonding pads 203 present a regular strip shape and have a specific width 206. There is an interval 207 existing between each of the bonding pads 203. However, as described above, the widths of these bonding pads 203 will become more and more narrow and the dimension of the interval 207 will become more and more small. Please refer to FIG. 1(B), which is a diagram illustrating the bonding pads of a conventional external circuit. The external circuit 300 in FIG. 1(B) includes bonding pads 303, a soft film 305 (or a soft circuit board) and dies 308 (shown in FIG. 1(C)) flipped on the soft film (namely, chip on film, COF). The bonding pads 303 are fabricated on the soft film 305 and resided in the interface region 304. The conventional bonding pads 303 demonstrate a regular strip shape and have a specific width 306. Between each of the bonding pads 303, there is an interval 307. The disposing position, the width 306 and the interval 307 of the bonding pads 303 are all corresponded with the bonding pads 203 in the interface region 204 of the display 200. Then after bonding together, the bonding pads 203 and the bonding pads 303 can communicate and exchange signals with each other.

Please refer to FIG. 1(C), which is a diagram illustrating the linkage between the conventional display and the external circuit. The FIG. 1(C) discloses a part 100 of a display. By using anisotropic conductive film (ACF) adhesive, the bonding pads (not shown in the FIG. 1(C)) within the interface region 204 of the display 200 are bonded with the bonding pads 303 within the interface region 304 of the external circuit 300 after aligning so that the display 200 and the external circuit 300 are electrically connected with each other. Then the display 200 and the external circuit 300 can communicate and exchange signals with each other.

Please refer to FIG. 1(D), which is a diagram illustrating the cross-section A-A′ in FIG. 1(C). The structure disclosed in FIG. 1(D) includes bonding pads 203 formed on the TFT glass substrate 205 and the bonding pads 303 formed on the soft film 305. Usually there is another conductive layer 208 (which is usually an ITO or a metal layer) will be further formed on the bonding pads 203 of the TFT glass substrate 205, so as to increase the interface region of the bonding pad 203. The bonding pads 303 and the bonding pads 203 are bonded together by ACF 150.

By observing the bonding pads existing in the conventional technology, they all present a uniform and regular strip shape and are configured in a parallel. It is thus known that, when the display are bonded with the external circuit, owing to the miniaturized dimension of the bonding pads, the probability the alignment deviation occurs is correspondingly increased. The alignment deviation will result in short circuit. Furthermore, the alignment deviation will cause the effective electrically bonding area which is originally supposed to be small becomes even much smaller, so that while the bonding pads of the display and the external circuit are electrically connected together by using the ACF, the amounts of the conductive anisotropic particles of the ACF for electrically bridging two bonding pads distributed within the respective effective electrically bonding area will become insufficient, which will result in poor conductive and electronic performance.

There are two principle non-man-made reasons causing the alignment deviation: (1) the heat expansion to COF or FPC; and (2) the different alignment deviations among different machine. The reason (1) can be avoided by reserving a shrinkage length that is pre-calculated and pre-estimated prior to bonding in advance. But the reason (2) is hardly to be anticipated in advance.

Typically, the machine can inherently tolerate some minor errors. However, with the increase of the numbers of the bonding pads and the miniaturization of the dimension itself, the accumulated alignment deviations will exceed the tolerable standard which leads to the failure of the tolerable error. Under the circumstance that the tolerable standard of the machine cannot be varied, it is necessary to modify and improve the bonding pads for overcoming the above-mentioned troubles.

Thus, in order to overcome the drawbacks in the prior art, an electrode array with multiple electrodes with variable width or length acting as the bonding pads is thus provided. The particular design in the present invention not only solves the problems described above, but also is easy to be implemented. Thus, the invention has the utility for the industry.

### SUMMARY OF THE INVENTION

The present invention proposes to reduce the total length and increase the width of the connecting part for each interface electrodes disposed on the display and the external circuit and to arrange the multiple connecting parts for each interface electrodes in a alternative configuration, so as to render the multiple connecting parts presenting likely a stagger pattern, a saw-like pattern or a zigzag pattern, so that the size for the effective electrically bonding area linking the interface electrodes can be effectively enlarged under the condition that the pitch or the entire size of the interface region is not varied. Thereby the alignment deviation is reduced for preventing the short circuit, more interface electrodes can be accommodated within the interface region under the condition that the pitch is fixed, or the pitch can be reduced to form a fine pitch effect for the condition that the amounts of the interface electrodes are fixed.

In accordance with the first aspect of the present invention, an electrode array is provided. The electrode array includes a substrate; and a plurality of electrodes, each of which has a first part with a first width and a second part with a second width different from the first width, wherein the plurality of electrodes are configured in compensation with each other on the substrate.

Preferably, the substrate is one of an inflexible substrate and a flexible substrate, the inflexible substrate is a glass substrate, the flexible substrate is one of a flexible printing circuit board (PCB) substrate and a soft substrate, the electrodes are indium tin oxide (ITO) or metal electrodes, the first part is used as a connector, and the second part is used as a conductor.

Preferably, the compensation is so presented that the first parts and the second parts form a formation in one selected from a group consisting of a stagger configuration, a saw-like configuration and a zigzag configuration.

Preferably, the electrode array is in one of two state being respectively disposed as an array of bonding pads at a signal-out terminal and a signal-in terminal, and on respective signal exchange ports of a first electronic element and a second electronic element so as to enable a signal communication therebetween.

Preferably, the signal-out terminal and the signal-in terminal are electrically connected with each other by an anisotropic conductive film (ACF) adhesive respectively.

In accordance with the second aspect of the present invention, an electrode array is provided. The electrode array includes a substrate; and a plurality of electrodes classified into a first class having a first length and a second class having a second length different from the first length.

In accordance with the third aspect of the present invention, a method of making an electrode array is provided. The method of making an electrode array includes steps of providing a substrate; and forming a plurality of electrodes on the substrate, each of which has a connecting part with a first width and a conductive part with a second width different from the first width.

Preferably, the method further includes steps of forming an insulating layer over the electrodes and the substrate; removing the insulating layer corresponding to the plurality of connecting parts therebeneath so as to unveil the plurality of connecting parts and form a plurality of openings; and forming a conductive layer over the plurality of openings.

Preferably, the insulating layer has a material including one selected from a group consisting of a silicon nitride, a silicon oxide, a resin, a polyimide and a combination thereof.

In accordance with the fourth aspect of the present invention, a method of making an electrode array is provided. The method of making an electrode array includes steps of providing a substrate; and forming on the substrate a plurality of electrodes classified into a first class having a first length and a second class having a second length different from the first length.

Other objects, advantages and efficacy of the present invention will be described in detail below taken from the preferred embodiments with reference to the accompanying drawings, in which:

### BRIEF DESCRIPTION OF THE DRAWINGS

FIG. 1(A) is a diagram illustrating the bonding pads utilized in a conventional display;

FIG. 1(B) is a diagram illustrating the bonding pads utilized in a conventional external circuit;

FIG. 1(C) is a diagram illustrating the linkage of conventional display and the external circuit;

FIG. 1(D) is a diagram illustrating the cross-section A-A′ of FIG. 1(C);

FIG. 2 is a diagram illustrating the first embodiment according to the present invention;

FIGS. 3(A) to 3(C) are diagrams illustrating the transition structures and processes during making the electrode array and the electrodes thereof according to the present invention;

FIG. 4 is a flow chart illustrating the processes for making the electrode array and the electrodes thereof according to the present invention;

FIG. 5 is a diagram illustrating a configuration of multiple bonding pads formed by an electrode array made by implementing the method for making an electrode array according to the present invention;

FIG. 6(A) is a diagram illustrating a second embodiment according to the present invention;

FIG. 6(B) is a diagram illustrating a third embodiment according to the present invention; and

FIG. 7 is a diagram illustrating the linking state among the bonding pads formed by the electrodes according to the present invention.

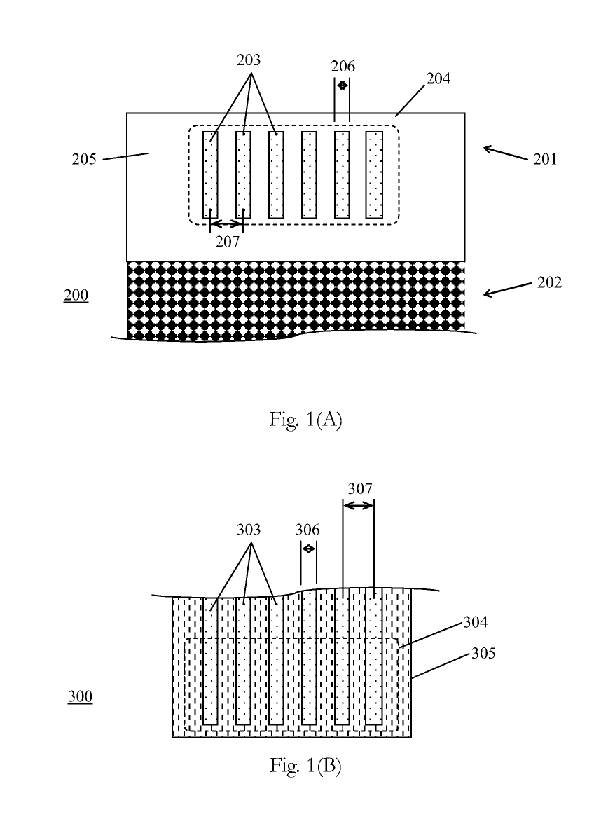

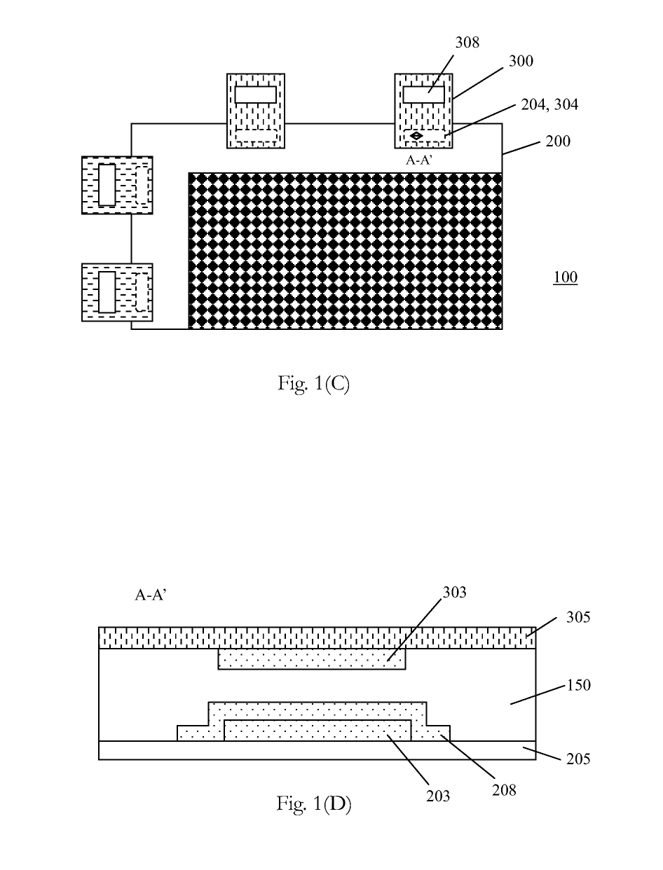

### DETAILED DESCRIPTION OF THE PREFERRED EMBODIMENT

The present invention will now be described more specifically with reference to the following embodiments. It is to be noted that the following descriptions of preferred embodiments of this invention are presented herein for purposes of illustration and description only; it is not intended to be exhaustive or to be limited to the precise form disclosed.

While the present invention is exemplarily described by reference to the preferred embodiments and examples regarding the mutual connection of a plurality of bonding pads of a display and a plurality of bonding pads of an external circuit for performing signal exchange and communication, it is to be understood that these examples are intended in an illustrative rather than in a limiting sense. It is contemplated that modifications and combinations will readily occur to those skilled in the art, which modifications and combinations will be within the spirit of the invention.

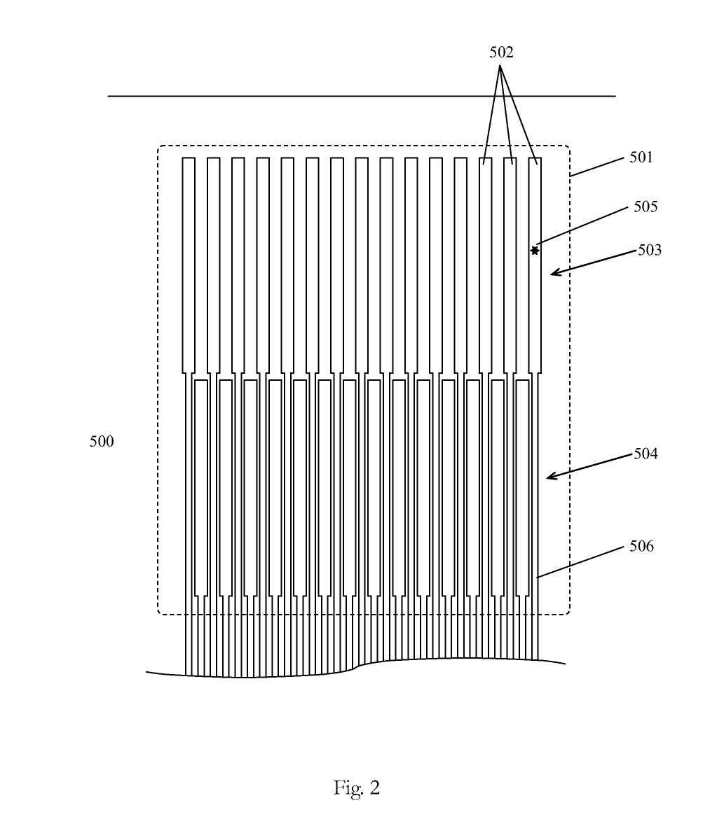

Please refer to FIG. 2, which is a diagram illustrating the first embodiment according to the present invention. The electrode array in the FIG. 2 disposed within the bonding area 501 of the display 500 includes multiple electrodes 502, each of which have the connecting part 503 and the conductive part 504 wherein a width 505 of the connecting part 503 is larger than a width 506 of the conductive part 504. When the multiple electrodes 502 are arranged, the connecting parts 503 are configured in compensation to each other on the substrate within the bonding area 501, in which the compensation is so presented that the connecting parts 503 preferably appear a configuration in one selected from a group consisting of a stagger pattern, a saw-like pattern and a zigzag pattern. Particularly, the multiple electrodes 502 shown in FIG. 2 are configured in an alternative configuration in density within the bonding area 501.

While an electrode array consisting of the above-mentioned variable width electrodes are disposed as the bonding pads or the interface electrodes within the bonding area of two different electronic devices, since the conductive part thereof has larger width, under the condition that the pitch value or the size of the entire bonding area is fixed, the effective electrically bonding area on the respective connecting parts of two opposite interface electrodes can be expanded, whereby the alignment deviation can be reduced for preventing the short circuit, more interface electrodes can accommodated in the fixed pitch within the bonding area, or, vice versa, the pitch value can be reduced to form a fine pitch effect for the condition that the amounts of the interface electrodes are fixed.

The above-mentioned electrodes 502 can be configured/made/formed/disposed on inflexible or flexible substrate for various printing circuit (FPC) substrate, chip on film (COF) substrate, chip on glass (COG) substrate, chip on board (COB) substrate or tape automated bonding (TAB) substrate.

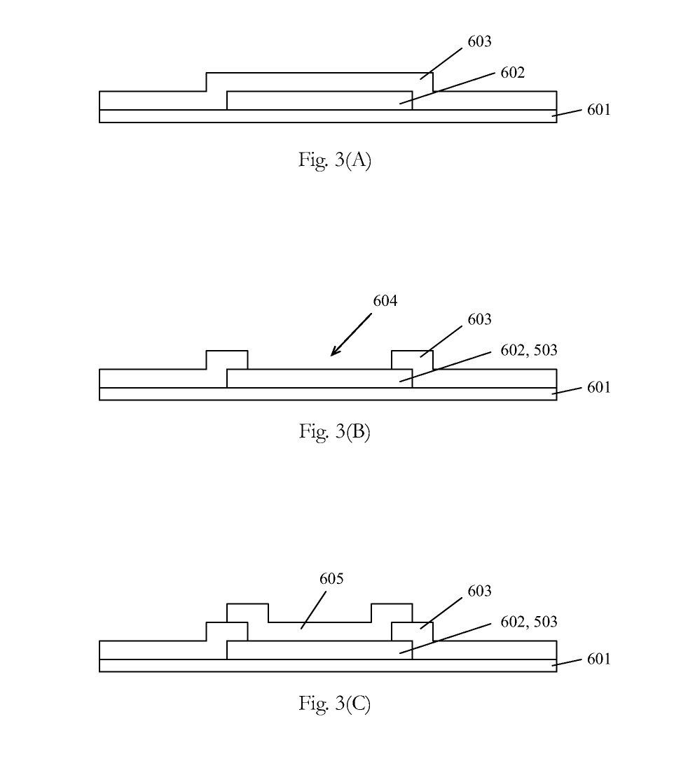

Please refer to FIGS. 3(A)˜3(C), which are diagrams illustrating the transition structures and processes during making the electrode array and the electrodes thereof according to the present invention. First of all, in FIG. 3(A), a substrate 601 is provided which substrate 601 is preferably an inflexible substrate or a flexible substrate. The inflexible substrate is preferably a glass substrate and the flexible substrate is preferably a FPC board substrate or a soft substrate. The substrate 601 is preferably an inflexible or a flexible substrate for a COF substrate, a COG substrate, a COB substrate or a TAB substrate.

Then, a first conductive layer 602 is formed on the substrate 601 by sputtering and other various conventional techniques. Subsequently, the conductive layer 602 is patterned as an electrode array consisting of the above-mentioned variable width electrodes by dry or wet etching and other various conventional techniques. Finally, an insulating layer 603 is formed over the entire substrate 601 and the conductive layer 602 so as to cover the formed electrode array.

Please direct to FIG. 3(B). The insulating layer 603 is removed to reveal the connecting part 503 so as to form multiple opens 604. Then please direct to FIG. 3(C). A second conductive layer 605 is consequently formed as a bonding pad over the multiple opens 604. The above-mentioned first and second conductive layers of 602 and 605 preferably have a material including an indium tin oxide (ITO) and a metal. The insulating layer 603 preferably has a material including a silicon nitride, a silicon oxide, a resin, a polyimide or a combination thereof.

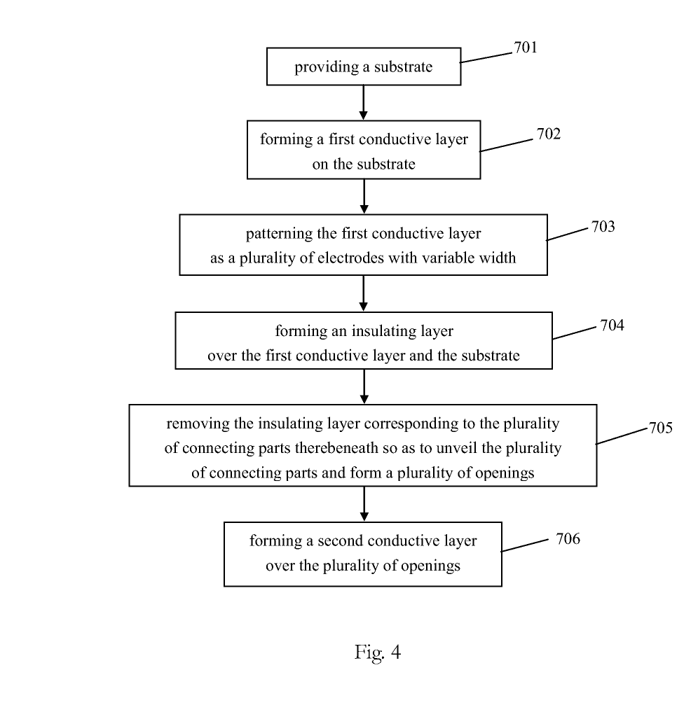

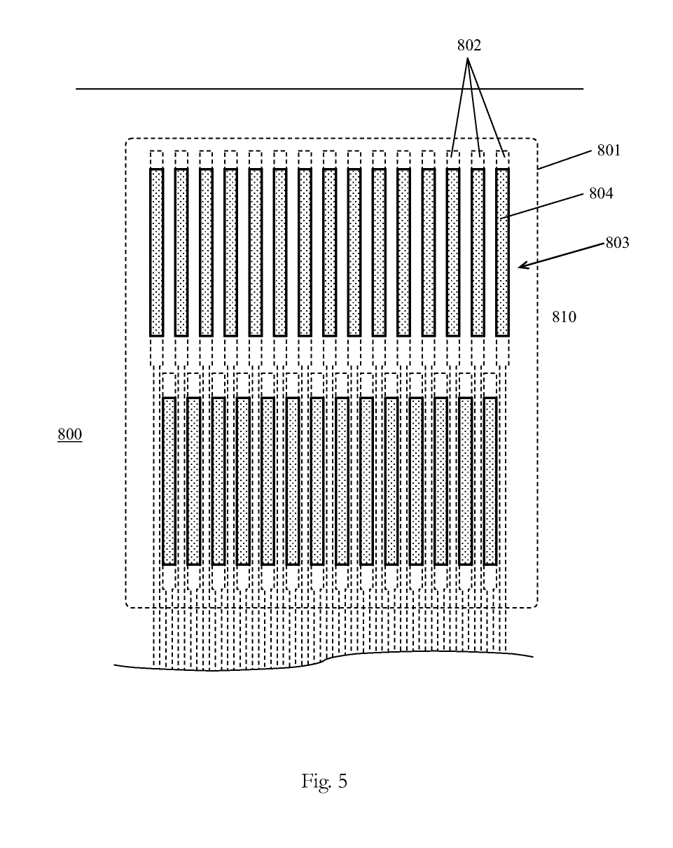

Please refer to FIG. 4, which is a flow chart illustrating the processes for making the electrode array and the electrodes thereof according to the present invention. The above-mentioned manufacturing steps can be summarized as follows. Step 701: providing a substrate; step 702: forming a first conductive layer on the substrate; step 703: patterning the first conductive layer as a plurality of electrodes with variable width, each of which has a connecting part with a first width and a conductive part with a second width different from the first width; step 704: forming an insulating layer over the first conductive layer and the substrate; step 705: removing the insulating layer corresponding to the plurality of connecting parts therebeneath so as to unveil the plurality of connecting parts and form a plurality of openings; and step 706: forming a second conductive layer over the plurality of openings.

Please direct to FIG. 5, which is a diagram illustrating a configuration of multiple bonding pads formed by an electrode array made by implementing the above-mentioned method for making an electrode array. From an aerial view, only the connecting parts 803 of the multiple electrodes 802 within the bonding area 801 of the display 800 are exposed as being a bonding pad 804 and the connecting parts 803 of the bonding pads 804 exposed within the bonding area 801 preferably form a formation in one selected from a group consisting of a stagger configuration, a saw-like configuration and a zigzag configuration. The remains in FIG. 5 are the insulating layer 810.

In accordance with the above-mentioned method, it is understood that making multiple above-mentioned electrodes with variable width in the bonding area of two electronic elements or two electronic devices respectively can benefit the signal exchange and the signal communication between two electronic elements or two electronic devices.

In accordance with the above-mentioned principle disclosed, a second embodiment can be correspondingly provided. A display and an external circuit acting as two electronic devices, which are intended in an illustrative rather than in a limiting sense, are embodied as follows.

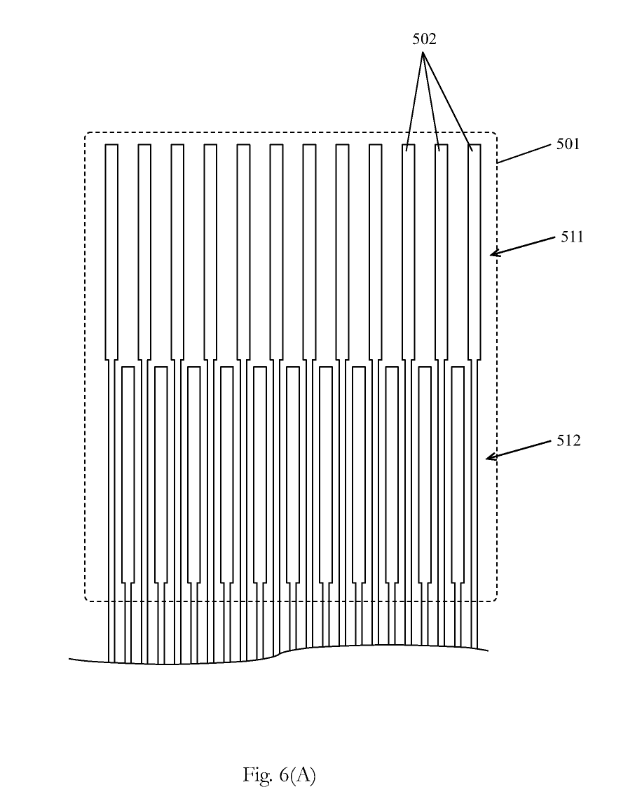

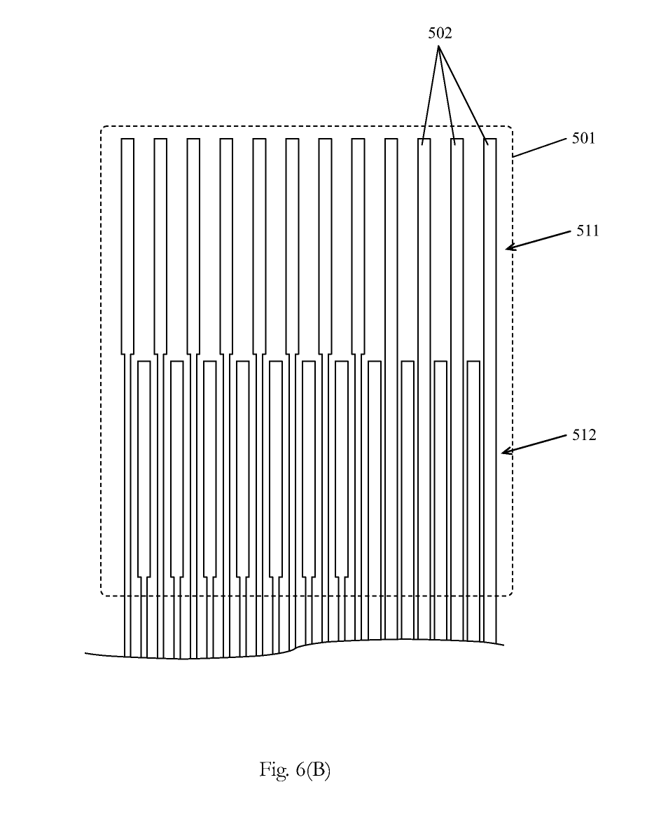

With continuous to the first embodiment of FIG. 2, please refer to FIG. 6(A), which is a diagram illustrating a second embodiment according to the present invention. The electrodes 502 of the present invention can be arranged within the bonding area 501 in a sparse arrangement that is not such a dense arrangement as shown in FIG. 2. Thus, the multiple electrodes 502 can be classified into a first class 511 having a first length and a second class 512 having a second length different from the first length. For the condition, the corresponding electrodes within the bonding area of another electronic device can be shaped in a conventional strip.

It is noted that, when the respective electrodes 502 have different length, the shape of each electrodes can be strip, namely in an invariable width, or still in a variable width.

A third embodiment is shown in FIG. 6(B). The electrodes 502 in FIG. 6(B) can be classified into a first class 511 having a first length and a second class 512 having a second length different from the first length.

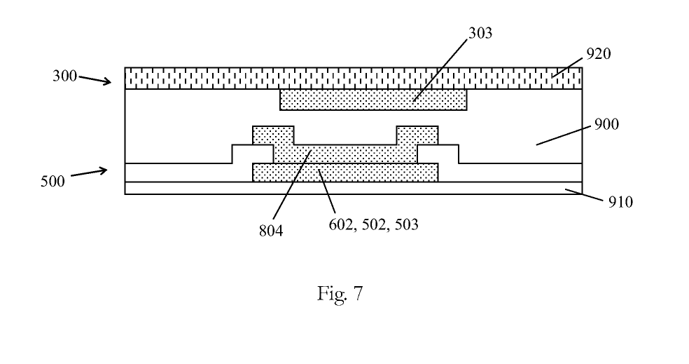

Please direct to FIG. 7, which is a diagram illustrating the linking state among the bonding pads formed by the electrodes according to the present invention. The bonding area of the display 500 of FIG. 7 has multiple electrodes 602 and 502 manufactured by the method for making an electrode array according to the above-mentioned first to third embodiments. A bonding pad 804 is correspondingly formed above the connecting part 503 of the electrodes 602 and 502. The electrodes 602 and 502 are preferably the electrode with invariable width but variable length or with variable width but invariable length made on the substrate 910 which form an electrode array (only a single electrode but not an electrode array shown in FIG. 7). The bonding area of the external circuit 300 in FIG. 7 has conventional strip electrode 303 made on the substrate 920, which also can be the multiple electrodes (not shown in FIG. 7) made by the method for making an electrode array according to the above-mentioned first to third embodiments. The electrodes 602, 502 and 503 on the display 500 and the electrode array thereof is electrically connected with the electrodes 303 of the external circuit 300 and the electrode array thereof by a conductive anisotropic conductive film adhesive 900. It is noted that the above-mentioned substrate 910 or 920 is preferably an inflexible substrate or a flexible substrate for the COF substrate, the COG substrate, the COB substrate, the FPC substrate or the TAB substrate.

It is noted that, as long as multiple electrodes manufactured by the method for making an electrode array according to the above-mentioned first to third embodiments of the present invention are disposed within the bonding area of one of the element or device of the above-mentioned two electronic elements or devices, since the conductive part thereof has larger width, under the condition that the pitch value or the size of the entire bonding area is fixed, the effective electrically bonding area on the respective connecting parts of two opposite interface electrodes can be expanded, whereby the alignment deviation can be reduced, more interface electrodes can accommodated in the fixed pitch within the bonding area, or, vice versa, the pitch value can be reduced to form a fine pitch effect for the condition that the amounts of the interface electrodes are fixed.

The electrode array of the present invention can be directly manufactured on an inflexible or a flexible substrate for the COF substrate, the COG substrate, the COB substrate, the TAB substrate or the FPC substrate and finally the bonding pads exiting in the bonding area will be configured in the compensation with each other on the substrate, wherein the compensation is so presented that the first parts and the second parts form a pattern in one selected from a group consisting of a stagger configuration, a saw-like configuration and a zigzag configuration.

While the invention has been described in terms of what is presently considered to be the most practical and preferred embodiments, it is to be understood that the invention needs not be limited to the disclosed embodiments. Therefore, it is intended to cover various modifications and similar configuration included within the spirit and scope of the appended claims, which are to be accorded with the broadest interpretation so as to encompass all such modifications and similar structures.

What is claimed is:

1. An electrode array, comprising:
a substrate; and
a plurality of electrodes, each of which has a first part with a first width and a second part with a second width different from the first width, wherein the plurality of electrodes are configured in compensation with each other on the substrate.

2. The electrode array according to claim 1, wherein the substrate is one of an inflexible substrate and a flexible substrate, the inflexible substrate is a glass substrate, the flexible substrate is one of a flexible printing circuit board (PCB) substrate and a soft substrate, the electrodes are indium tin oxide (ITO) or metal electrodes, the first part is used as a connector, and the second part is used as a conductor.

3. The electrode array according to claim 1, wherein the compensation is so presented that the first parts and the second parts form a formation in one selected from a group consisting of a stagger configuration, a saw-like configuration and a zigzag configuration.

4. The electrode array according to claim 1 being in one of two state being respectively disposed as an array of bonding pads at a signal-out terminal and a signal-in terminal, and on respective signal exchange ports of a first electronic element and a second electronic element so as to enable a signal communication therebetween.

5. The electrode array according to claim 4, wherein the signal-out terminal and the signal-in terminal are electrically connected with each other by an anisotropic conductive film (ACF) adhesive respectively.

6. An electrode array, comprising:
a substrate; and
a plurality of electrodes classified into a first class having a first length and a second class having a second length different from the first length.

7. A method of making an electrode array, comprising steps of:
providing a substrate; and
forming a plurality of electrodes on the substrate, each of which has a connecting part with a first width and a conductive part with a second width different from the first width.

8. The method according to claim 7, further comprising steps of:
forming an insulating layer over the electrodes and the substrate;
removing the insulating layer corresponding to the plurality of connecting parts therebeneath so as to unveil the plurality of connecting parts and form a plurality of openings; and
forming a conductive layer over the plurality of openings.

9. The method according to claim 8, wherein the insulating layer has a material including one selected from a group consisting of a silicon nitride, a silicon oxide, a resin, a polyimide and a combination thereof.

10. A method of making an electrode array, comprising steps of:
providing a substrate; and
forming on the substrate a plurality of electrodes classified into a first class having a first length and a second class having a second length different from the first length.
